(19) United States
(12) Patent Application Publication
(10) Pub. No.: US 2011/0241042 A1
(43) Pub. Date: Oct. 6, 2011

(54) NANOCRYSTAL-BASED OPTOELECTRONIC DEVICE AND METHOD OF FABRICATING THE SAME

(75) Inventors: Miin-Jang Chen, Taipei City (TW); Shieh-Yang Sun, Taipei City (TW); Fu-Hsiang Su, Taipei City (TW); Ching-Huang Chen, Taipei City (TW); Ying-Tsang Shih, Taipei City (TW)

(73) Assignee: Miin-Jang Chen, Taipei City (TW)

(21) Appl. No.: 12/896,938

(22) Filed: Oct. 4, 2010

(30) Foreign Application Priority Data
Apr. 2, 2010 (TW) 099110307

(51) Int. Cl. H01L 33/30; H01L 33/00

(52) U.S. Cl. 257/94; 438/47; 257/E33.001; 257/E33.027; 977/773

(57) ABSTRACT

The invention discloses a nanocrystal-based optoelectronic device and method of fabricating the same, such as light-emitting diode, photodetector, solar cell, etc. The optoelectronic device according to the invention includes a substrate of a first conductive type, N active layers formed on the substrate and a transparent conductive layer formed on the most-top active layer. Each active layer is constituted by a plurality of nanocrystals. Each nanocrystal is wrapped by a passivation layer.

### CROSS-REFERENCE TO RELATED APPLICATION

This utility application claims priority to Taiwan Application Serial Number 099110307, filed Apr. 2, 2010, which is incorporated herein by reference.

### BACKGROUND OF THE INVENTION

1. Field of the Invention

The invention relates to a nanocrystal-based optoelectronic device and method of fabricating the same, such as a light-emitting diode, a photodetector, a solar cell, etc. And more particularly, the invention relates to a nanocrystal-based optoelectronic device including a high photoelectric conversion efficiency and method of fabricating the same.

On the relative technical background of the invention, please refer to the following technical literatures:

[1] Lalic N and Linnros J 1998 J. Lumin. 80 263;

[2] Fujita S and Sugiyama N 1999 Appl. Phys. Lett. 74 308;

[3] Sato K and Hirakuri L 2006 Thin Solid Films 515 778;

[4] Walters R J, Bourianoff G I and Atwater H A 2005 Nat. Mater. 4 143;

[5] Pavesi L, Negro L D, Mazzoleni C, Franzo G and Priolo F 2000 Nature 408 440;

[6] Negro L D, Cazzanelli M, Daldosso N, Gaburro Z, Pavesi L, Priolo F, Pacifici D, Franzo G and Iacona F 2003 Physica E 16 297;

[7] Khriachtchev L, Rasanen M, Novikov S and Sinkkonen J 2001 Appl. Phys. Lett. 79 1249;

[8] Luterova K, Pelant I, Mikulskas I, Tomasiunas R, Muller D, Grob J J, Rehspringer J L and Honerlage B 2002 J. Appl. Phys. 91 2896;

[9] Ruan J, Fauchet P M, Negro L D, Cazzanelli M and Pavesi L 2003 Appl. Phys. Lett. 83 5479;

[10] Shimizu-Iwayama T, Nakao S and Saitoh K 1994 Appl. Phys. Lett. 65 1814;

[11] Song H Z and Bao X M 1997 Phys. Rev. B 55 6988;

[12] Shimizu-Iwayama T, Nakao S, Saitoht K and Itohs N 1994 J. Phys.: Condens. Matter 6 L601;

[13] Iacona F, Bongiorno C, Spinella C, Boninelli S and Priolo F 2004 J. Appl. Phys. 95 3723; and

[14] Peralvarez M, Garcia C, Lopez M, Garrido B, Barreto J and Dominguez C 2006 Appl. Phys. Lett. 89 051112.

2. Description of the Prior Art

Silicon is the prevailing semiconductor material not only in microelectronics, but also in photonic applications. A number of silicon-based active devices, such as optical modulators and photodetectors, have been developed for the realization of photonic integrated circuits.

However, the fundamental challenge is to fabricate efficient silicon-based light-emitting devices since bulk Si is an indirect-bandgap semiconductor and consequently exhibits very low light emission efficiency.

In the past decade, a considerable number of studies have been carried out to enhance the light emission efficiency from Si based nanostructures such as Si/SiO₂ superlattices, Si nanocrystals, porous Si, and nano-patterned Si. Among these Si nanostructures, Si nanocrystals embedded in a SiO₂ matrix have attracted substantial attention due to the demonstration of efficient light-emitting devices [1-4] and the observation of stimulated emission [5-9].

Preparation of sub-stoichiometric silica films with excess Si together with a subsequent high temperature treatment were widely utilized to fabricate Si nanocrystals embedded in a SiO₂ matrix. These sub-stoichiometric silica films were usually prepared by ion-implantation of Si into thermally grown SiO₂ layers or by plasma enhanced chemical vapor deposition (PECVD) [10-12]. The high-temperature post-deposition annealing causes a phase separation between Si and SiO₂ in the films, accordingly, resulting in the formation of Si nanocrystals embedded in a SiO₂ matrix. However, the disadvantage of these technologies is that the processing parameters and the annealing conditions need to be carefully controlled to produce Si nanocrystals with well-defined sizes and uniformity.

Furthermore, not only Si nanocrystals, but also a number of nanocrystal materials, such as Ge, ZnO, ZnS, PbS, CdSe, CdTe, CdS, ZnSe, InAs, InP, CdSe(core)/CdS(shell) core-shell structure, CdSe(core)/ZnS(shell) core-shell structure, and CdTe(core)/CdS(shell) core-shell structure, can serve as a light emitting material or light absorbing material.

Accordingly, one scope of the invention is to provide a nanocrystal-based optoelectronic device and method of fabricating the same. An optoelectronic device according to the invention has high photoelectric conversion efficiency, and a fabricating method according to the invention does not have the processing parameters and the annealing conditions which are difficult to be controlled.

### SUMMARY OF THE INVENTION

A nanocrystal-based optoelectronic device according to a preferred embodiment of the invention includes a substrate of a first conductive type, N active layers, and a transparent conductive layer of a second conductive type, where N is a natural number. The N active layers are formed on the substrate. In particular, each active layer is constituted by a plurality of nanocrystals, and each nanocrystal is wrapped by a first passivation layer. The transparent conductive layer is formed on the most-top active layer among the N active layers. A light emitting diode (LED) is taken as the nanocrystal-based optoelectronic device according to the invention for explanation. When a current is injected into the nanocrystal-based optoelectronic device according to the invention, electrons and holes recombine radiatively in each nanocrystal to emit a light.

In one embodiment, the substrate can be formed of Si, GaAs, GaN, AlₓGa₁₋ₓ, As, InP, GaₓAl₁₋ₓN, SiC, ZnO, Tin-doped Indium Oxide(ITO), ZnₓMg₁₋ₓO, ZnₓMg₁₋ₓO:Al, ZnₓMg ₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, or CuInO₂:Sn, where 0≦x≦1.

In one embodiment, each nanocrystal can be formed of Si, and the first passivation layer is formed by a thermal oxidation process or an atomic layer deposition process.

In one embodiment, each nanocrystal can be formed of Ge, ZnO, ZnS, PbS, CdSe, CdTe, CdS, ZnSe, InAs, InP, CdSe(core)/CdS(shell) core-shell structure, CdSe(core)/ZnS(shell) core-shell structure, and CdTe(core)/CdS(shell) core-shell structure, and the first passivation layer is formed by an atomic layer deposition process.

In one embodiment, the transparent conductive layer is formed of ZnO, Tin-doped Indium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, and CuInO₂:Sn, where 0≦x≦1.

A method of fabricating a nanocrystal-based optoelectronic device according to a preferred embodiment of the invention, firstly, is to prepare a substrate of a first conductive type. Then, the fabricating method according to the invention is to form N active layers on the substrate, where N is a natural number. In particular, each active layer is constituted by a plurality of nanocrystals, and each nanocrystal is wrapped by a first passivation layer. Final, the fabricating method according to the invention is to form a transparent conductive layer of a second conductive type on the most-top active layer among the N active layers.

The advantage and spirit of the invention may be understood by the following recitations together with the appended drawings.

BRIEF DESCRIPTION OF THE APPENDED DRAWINGS

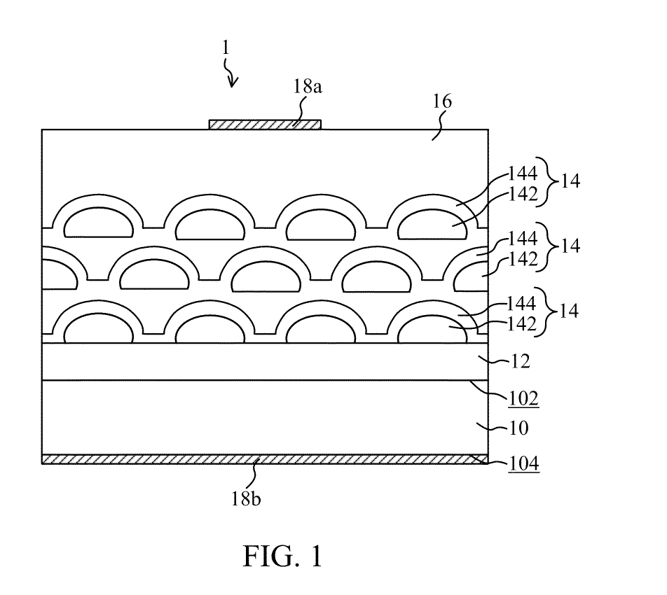

FIG. 1 illustratively shows a nanocrystal-based optoelectronic device 1 according to a preferred embodiment of the invention.

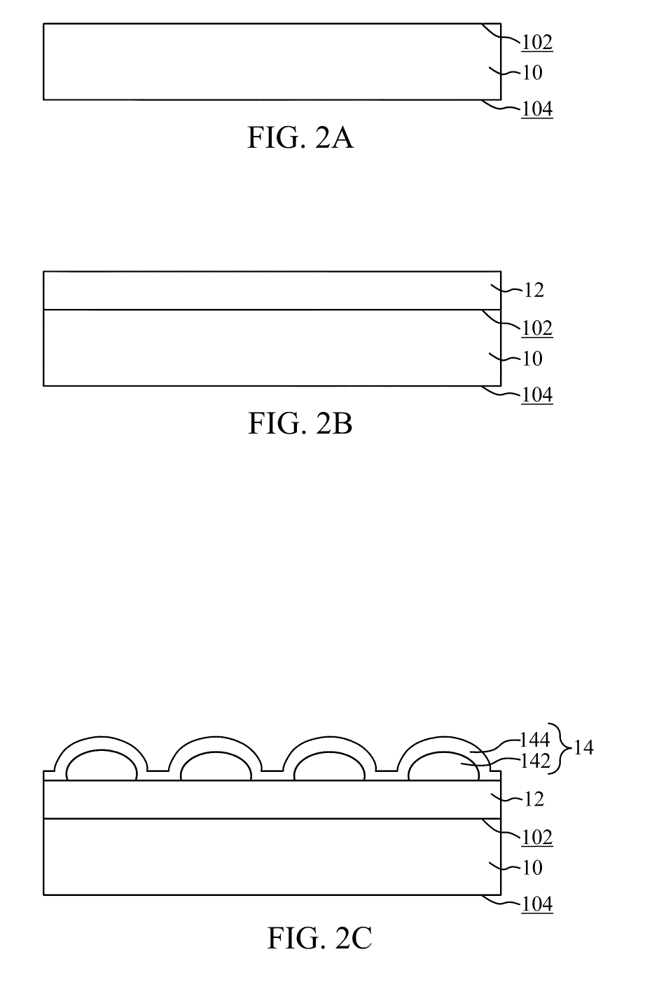

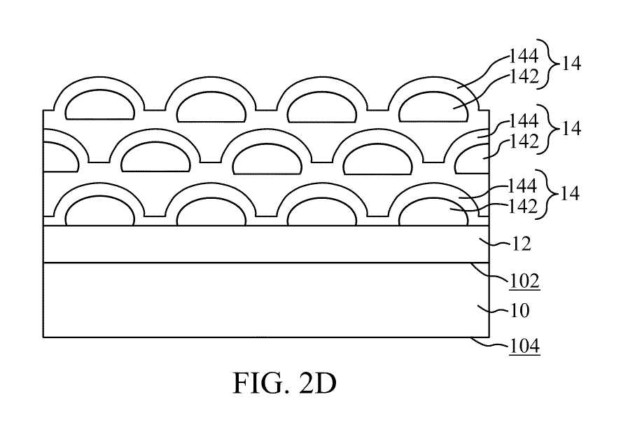

FIG. 2A through 2D illustratively show a method of fabricating a nanocrystal-based optoelectronic device 1 shown in FIG. 1 according to a preferred embodiment of the invention.

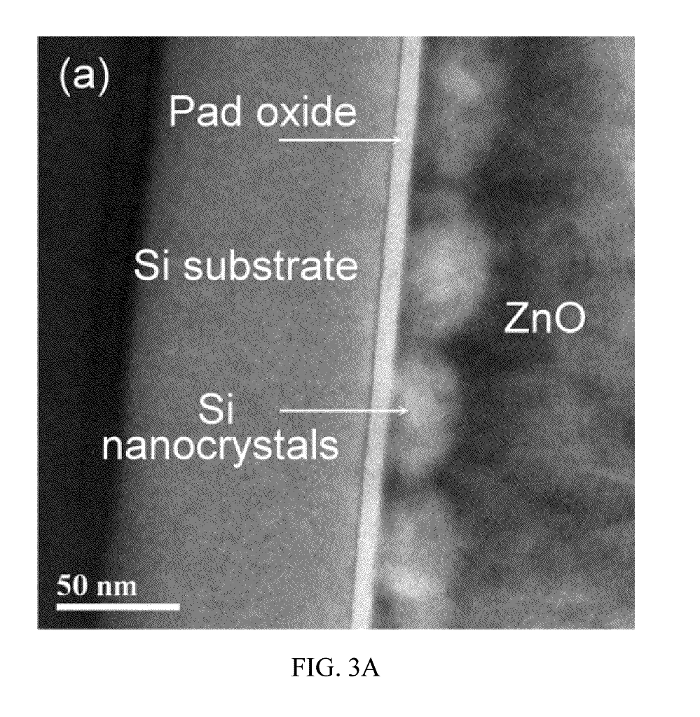

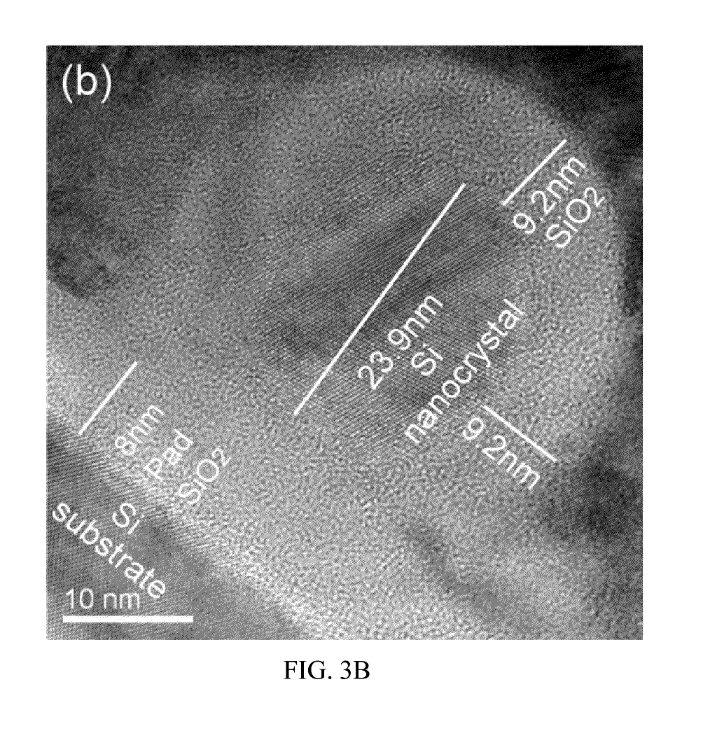

FIG. 3A is a cross-sectional transmission electron microscope image of the n-ZnO/SiO₂-Si nanocrystals-SiO₂/p-Si heterostructure LED which is fabricated according to the invention.

FIG. 3B is a high-resolution transmission electron microscope image of the n-ZnO/SiO₂-Si nanocrystals-SiO₂/p-Si heterostructure LED which is fabricated according to the invention.

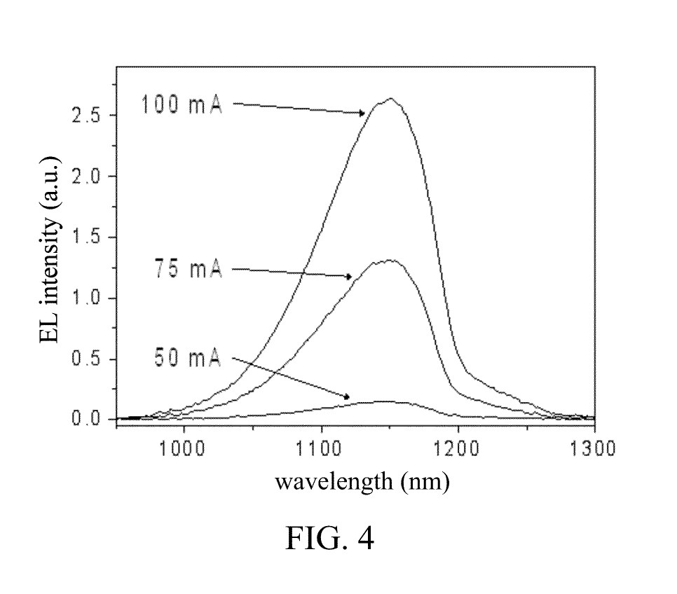

FIG. 4 is a room-temperature electroluminescence spectrum of the n-ZnO/SiO₂-Si nanocrystals-SiO₂/p-Si heterostructure LED which is fabricated according to the invention at various injection currents.

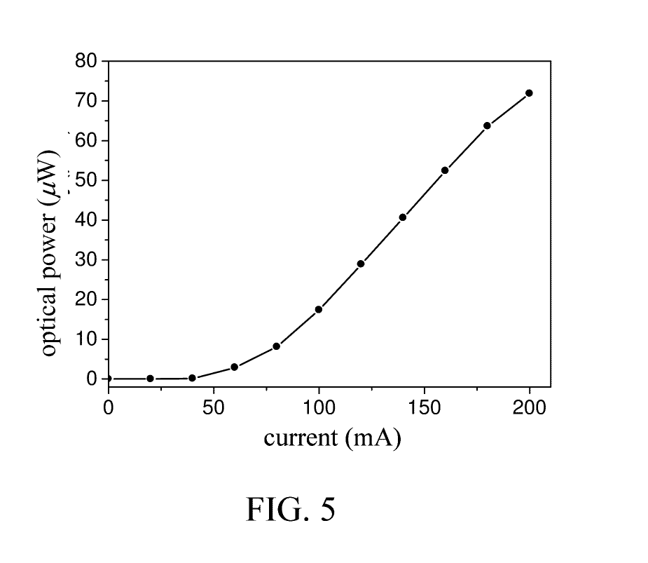

FIG. 5 shows the measured optical power versus DC injection current (L-I) curves of the n-ZnO/SiO₂-Si nanocrystals-SiO₂/p-Si heterostructure LED which is fabricated according to the invention.

### DETAILED DESCRIPTION OF THE INVENTION

Some preferred embodiments and practical applications of this present invention would be explained in the following paragraph, describing the characteristics, spirit, and advantages of the invention.

Please refer to FIG. 1, FIG. 1 illustratively shows a sectional view of a nanocrystal-based optoelectronic device 1 according to a preferred embodiment of the invention.

As shown in FIG. 1, the nanocrystal-based optoelectronic device 1 according to the invention includes a substrate 10 of a first conductive type, N active layers 14, and a transparent conductive layer 16 of a second conductive type, where N is a natural number. In the case shown in FIG. 1, it only illustratively shows three active layers 14 as an example for explanation.

The N active layers 14 are formed on the substrate 10, and each active layer 14 is constituted by a plurality of nanocrystals 142. Also in the case shown in FIG. 1, the N active layers 14 are formed in sequence on the substrate 10, each active layer 14 is constituted by a plurality of nanocrystals 142 arranged in a single layer, and each nanocrystal 142 is wrapped by a first passivation layer 144. The transparent conductive layer 16 is formed on the most-top active layer 14 among the N active layers 14.

Also as shown in FIG. 1, according to another preferred embodiment of the invention, the nanocrystal-based optoelectronic device 1 further includes a second passivation layer 12. The second passivation layer 12 is first formed on an upper surface 102 of the substrate 10. The N active layers 14 are formed in sequence on the second passivation layer 12. In the case shown in FIG. 1, the N active layers 14 are formed in sequence on the second passivation layer 12.

The second passivation layer 12 can lower the defect density of an interface between the nanocrystal 142 and the substrate 10, such as lowering the effect of dangling bond, and provides a function of confining carriers in the nanocrystal 142. The first passivation layer 144 provides a surface passivation function to reduce the nonradiative recombination of the carriers at the surface of nanocrystal 142, and contribute to the carrier confinement effect of confining carriers in the nanocrystal 142.

Also shown in FIG. 1, according to another preferred embodiment of the invention, the nanocrystal-based optoelectronic device 1 further includes a top electrode 18a formed on the transparent conductive layer 16, and a bottom electrode 18b formed on a bottom surface 104 of the substrate 10, such as an aluminum electrode formed by a thermal evaporation system. However, the formation and the relating designs of the electrodes depend on practical requirement of the optoelectronic device.

A light emitting diode is taken as the nanocrystal-based optoelectronic device 1 according to the invention for explanation. When a current is injected into the nanocrystal-based optoelectronic device 1 according to the invention through the top electrode 18a and bottom electrode 18b, electrons and holes recombine radiatively in each nanocrystal 142 to emit a light.

In one embodiment, each nanocrystal 142 can be formed of Si, and the first passivation layer 144 can be formed by a thermal oxidation process or an atomic layer deposition (ALD) process. In this process called atomic layer deposition process refers to an atomic layer deposition process and/or a plasma-enhanced atomic layer deposition process (or a plasma-assisted atomic layer deposition process), and is the same as the following process called atomic layer deposition process. That is to say, in practical application, the atomic layer deposition based process can be an atomic layer deposition process, a plasma-enhanced atomic layer deposition process, a plasma-assisted atomic layer deposition process, or combination thereof, such as combination of the atomic layer deposition process and the plasma-enhanced atomic layer deposition process or combination of the atomic layer deposition process and the plasma-assisted atomic layer deposition process. Using the plasma-enhanced ALD process or the plasma-assisted ALD process can ionize precursors, so as to lower the processing temperature and to improve the quality of films. It is noticeable that the atomic layer deposition process is also named as Atomic Layer Epitaxy (ALE) process or Atomic Layer Chemical Vapor Deposition (ALCVD) process, so that these processes are actually the same. If the first passivation layer 144 is formed by the atomic layer deposition process, the first passivation layer 144 is essentially a multi-atomic-layer structure, and offers many benefits such as low defect density, accurate thickness and composition control, high uniformity over a large area, excellent conformality and good step coverage, low deposition temperature, and good reproducibility. The high-quality passivation layers are able to be successfully formed on the surface of each nanocrystal by the atomic layer deposition process with high uniformity and good step coverage.

In one embodiment, each nanocrystal 142 can be formed of Ge, ZnO, ZnS, PbS, CdSe, CdTe, CdS, ZnSe, InAs, InP, CdSe(core)/CdS(shell) core-shell structure, CdSe(core)/ZnS(shell) core-shell structure, and CdTe(core)/CdS(shell) core-shell structure, and the first passivation layer 144 is formed by an atomic layer deposition process. If the first passivation layer 144 is formed by the atomic layer deposition process, the first passivation layer 144 is essentially a multi-atomic-layer structure, and offers many benefits such as low defect density, accurate thickness and composition control, high uniformity over a large area, excellent conformality and good step coverage, low deposition temperature, and good reproducibility. The high-quality passivation layers can be successfully formed on the surface of each nanocrystal by the atomic layer deposition process with high uniformity and good step coverage.

In one embodiment, the first conductive type is p-type, and the second conductive type is n-type. In another embodiment, the first conductive type is n-type, and the second conductive type is p-type.

In one embodiment, the substrate 10 can be formed of Si, GaAs, GaN, AlₓGa₁₋ₓAs, InP, GaₓAl₁₋ₓN, SiC, ZnO, Tin-doped Iridium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, or CuInO₂:Sn, where 0≦x≦1. If the substrate 10 is formed of Si, the second passivation layer 12 will be formed by a thermal oxidation process or an atomic layer deposition process. If the substrate 10 is formed of GaAs, GaN, AlₓGa₁₋ₓAs, InP, GaₓAl₁₋ₓN, SiC, ZnO, Tin-doped Iridium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, or CuInO₂:Sn, the second passivation layer 12 will be formed by an atomic layer deposition process.

In one embodiment, the transparent conductive layer 16 is formed of ZnO, Tin-doped Indium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, or CuInO₂:Sn, where 0≦x≦1.

In practical application, if the second passivation layer 12 and the first passivation layer 144 are formed by the atomic layer deposition process, the second passivation layer 12 or the first passivation layer 144 will be formed of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSe_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSe_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or other compounds, or a mixture therebetween, but not limit to the above.

Please refer to FIG. 2A through 2D. These FIGs illustratively show sectional views of a method for fabricating a nanocrystal-based optoelectronic device 1 shown in FIG. 1 according to a preferred embodiment of the invention.

As shown in FIG. 2A, firstly, the fabricating method according to the invention is to prepare a substrate 10 of a first conductive type.

Then, the fabricating method according to the invention is to form a second passivation layer 12 on a top surface 102 of the substrate 10, as shown in FIG. 2B.

Next, the fabricating method according to the invention is to form N active layers 14 on the second passivation layer 12, where N is a natural number. In particular, each active layer 14 is constituted by a plurality of nanocrystals 142, and each nanocrystal 142 is wrapped by a first passivation layer 144. As shown in FIG. 2C, different from the prior art, the fabricating method according to the invention, firstly, is to form the plurality of nanocrystals 142, for example, arranged in a single layer on the second passivation layer 12, and then to form the first passivation layer 144 wrapping the plurality of nanocrystals 142 for forming a first active layer 14. Next, each active layer 14 is also formed from that the plurality of nanocrystals 142, for example, arranged in a single layer is formed on the previous active layer 14, and then the first passivation layer 144 wrapping the plurality of nanocrystals 142 is formed for forming the corresponding active layer 14. Therefore, the fabricating method according to the invention is able to successfully form N active layers 14 on the second passivation layer 12, as shown in FIG. 2D. And it needs to be stressed that the fabricating method according to the invention does not include the processing parameters and the annealing conditions which are difficult to be controlled.

According to another preferred embodiment of the invention, a method of fabricating a nanocrystal-based optoelectronic device 1 is to form the N active layers on the substrate 10 directly.

Finally, the fabricating method according to the invention is to form a transparent conductive layer 16 of a second conductive type on the most-top active layer 14 among the N active layers 14.

Further, the fabricating method according to the invention is to form a top electrode 18a on the transparent conductive layer 16, and form a bottom electrode 18b on a bottom surface 104 of the substrate 10, i.e., the nanocrystal-based optoelectronic device 1 shown in FIG. 1 is finished. However, the formation and the relating designs of the electrodes depend on practical requirement of the optoelectronic device.

In practical application, the possible conductive type, composition, and process relating to each layer have been described in detail above, and it will not be described again here.

In a case, the n-ZnO/SiO₂—Si nanocrystals-SiO₂/p-Si heterostructure LED according to the invention is fabricated and its optoelectronic characteristics have been measured. First, p-type(100) Si with a resistivity of 5-8 Ωcm is used as a substrate. Then, the p-type substrate is oxidized in a dry oxygen atmosphere at 800° C. to yield 4 nm thick SiO₂ as a passivation layer. Next, Si nanocrystals are deposited on the SiO₂ passivation layer by low pressure chemical vapor deposition (LPCVD), where the average diameter of as-deposited Si nanocrystals is about 35 nm. The spacing between the Si nanocrystals is about 45 nm, and the density of the Si nanocrystals is approximately 8.1×10⁹ cm⁻². The Si nanocrystals can also be fabricated previously by another techniques, and then to be spread on the substrate by spin coating method.

Afterward, thermal oxidation at 850° C. is carried out to grow a SiO₂ passivation layer on the Si nanocrystals, where the oxide thickness of the SiO₂ passivation layer is around 10 nm. Subsequently, an Al-doped ZnO (ZnO:Al) layer with a thickness of 136 nm is deposited at 180° C. by the atomic layer deposition process. By controlling the ratio of Al-doped and the thickness of Al-doped ZnO layer, the Al-doped ZnO layer can serve as an electron injection layer, a transparent conductive layer, as well as an anti-reflection coating layer to enhance external quantum efficiency of the light-emitting diode. The chemical reactions proceed only at the surface of the substrate during the atomic layer deposition process, leading to self-limiting and layer-by-layer growth. The atomic layer deposition process adopted by the invention has the following advantages: (1) the ability to control the formation of the material in nano-metric scale; (2) the ability to control the film thickness and composition more precisely; (3) large-area and large-batch capacity; (4) excellent uniformity; (5) excellent conformality and step coverage; (6) pinhole-free structure; (7) low defect density; and (8) low deposition temperatures, etc. A cross-sectional transmission electron microscope image of the n-ZnO/SiO₂-Si nanocrystals-SiO₂/p-Si heterostructure LED is shown in FIG. 3A, and a high-resolution transmission electron microscope image of the n-ZnO/SiO₂—Si nanocrystals-SiO₂/p-Si heterostructure LED is shown in FIG. 3B. In FIG. 3A and FIG. 3B, the Si substrate is marked “Si substrate”, the SiO₂ passivation layer on the Si substrate is marked “Pad oxide” or “Pad SiO₂”, the Si nanocrystals is marked “Si nanocrystals”, the SiO₂ passivation layer on the surface of Si nanocrystals is marked “SiO₂”, and Al-doped ZnO layer is marked “ZnO”. Please see FIG. 4, FIG. 4 is an electroluminescence spectrum of the above n-ZnO/SiO₂-Si nanocrystals-SiO₂/p-Si heterostructure LED. Please see FIG. 5, FIG. 5 shows the measured optical power versus DC injection current (L-I) curves of the above n-ZnO/SiO₂-Si nanocrystals-SiO₂/p-Si heterostructure LED.

FIG. 4 and FIG. 5 show that a spectra peak wavelength of the above n-ZnO/SiO₂-Si nanocrystals-SiO₂/p-Si heterostructure LED is around 1150 nm, which corresponds to the bandgap energy of bulk Si. The measured external quantum efficiency from this heterostructure LED is up to 4.3×10⁻⁴, which is two orders of magnitude greater than that of bulk Si. The internal quantum efficiency of this heterostructure LED is estimated to be of the order of 10⁻³. The turn-on voltage in the current-voltage characteristics of this heterostructure LED is only about 3.6 V, which is low enough to be integrated with silicon microelectronics. In addition, those structures and fabrication processes are fully compatible with silicon-based ultra-large-scale integration technology.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A nanocrystal-based optoelectronic device, comprising:
a substrate of a first conductive type;
N active layers formed on the substrate, N being a natural number, each active layer being constituted by a plurality of nanocrystals, each nanocrystal being wrapped by a first passivation layer; and
a transparent conductive layer of a second conductive type, formed on the most-top active layer among the N active layers.

2. The nanocrystal-based optoelectronic device of claim 1, further comprising:
a second passivation layer, formed between the substrate and the most-bottom active layer among the N active layers by a thermal oxidation process or an atomic layer deposition process, and said second passivation layer being formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, CO₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSe_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSe_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.

3. The nanocrystal-based optoelectronic device of claim 1, wherein the substrate is formed of one selected from the group consisting of Si, GaAs, GaN, AlₓGa₁₋ₓAs, InP, GAₓAl₁₋ₓN, SiC, ZnO, Tin-doped Indium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCa ₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Ga, and CuInO₂:Sn, where 0≦x≦1, and the transparent conductive layer is formed of one selected from the group consisting of ZnO, Tin-doped Indium Oxide (ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, and CuInO₂:Sn, where 0≦x≦1.

4. The nanocrystal-based optoelectronic device of claim 1, wherein each nanocrystal is formed of Si, the first passivation layer is formed by a thermal oxidation process or an atomic layer deposition process, and said first passivation layer is formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSe_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSeₓ, ZnO, ZnS, ZnSe, ZnTe, ZnF₂, ZrO₂, Zr₃N₄, PrOₓ, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.

5. The nanocrystal-based optoelectronic device of claim 1, wherein each nanocrystal is formed of one selected from the group consisting of Ge, ZnO, ZnS, PbS, CdSe, CdTe, CdS, ZnSe, InAs, InP, CdSe(core)/CdS(shell) core-shell structure, CdSe(core)/ZnS(shell) core-shell structure, and CdTe(core)/CdS(shell) core-shell structure, the first passivation layer is formed by an atomic layer deposition process, and said first passivation layer is formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAl₃O, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSe_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSe_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.

6. A method of fabricating a nanocrystal-based optoelectronic device, comprising the steps of:
(a) preparing a substrate of a first conductive type;
(b) forming N active layers on the substrate, N being a natural number, wherein each active layer is constituted by a plurality of nanocrystals, and each nanocrystal is wrapped by a first passivation layer; and
(c) forming a transparent conductive layer of a second conductive type on the most-top active layer among the N active layers.

7. The method of claim 6, between step (a) and step (b) further comprising the step of:
forming a second passivation layer on the substrate by a thermal oxidation process or an atomic layer deposition process, wherein N active layers is formed on said second passivation layer, and said second passivation layer is formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSeₓ, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSeₓ, ZnO, ZnS, ZnSe, ZnTe, ZnF₂, ZrO₂, Zr₃N₄, PrOₓ, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.

8. The method of claim 6, wherein the substrate is formed of one selected from the group consisting of Si, GaAs, GaN, AlₓGa₁₋ₓAs, InP, GaₓAl₁₋ₓN, SiC, ZnO, Tin-doped Indium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓ,O:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO₂, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga and CuInO₂:Sn, where 0≦x≦1, and the transparent conductive layer is formed of one selected from the group consisting of ZnO, Tin-doped Indium Oxide(ITO), ZnₓMg₁₋ₓO, ZnₓMg₁₋ₓO:Al, ZnₓMg₁₋ₓO:Ga, ZnₓMg₁₋ₓO:In, ZnₓMg₁₋ₓO:N, ZnₓMg₁₋ₓO:P, ZnₓMg₁₋ₓO:As, InGaZnO₄(IGZO), NiO, Cu₂O, ZnO:N, ZnO:P, ZnO:As, SrCu₂O₂, LaCuOS, LaCuOSe, LaCuOTe, CuAlO₂, CuGaO₂, CuGa₁₋ₓFeₓO₂, CuInO₂, CuIn₁₋ₓCaₓO2, CuCrO₂, CuCr₁₋ₓMgₓO₂, CuScO₂, CuSc₁₋ₓMgₓO₂, CuYO₂, CuY₁₋ₓCaₓO₂, AgInO₂, AgCoO₂, In₂O₃:Sn, SnO₂:Sb, SnO₂:F, SnO₂, SnO₂:Al, SnO₂:Ga, SnO₂:In, SnO₂:N, ZnO:Al, ZnO:Ga, and CuInO₂:Sn, where 0≦x≦1.

9. The method of claim 6, wherein each nanocrystal is formed of Si, the first passivation layer is formed by a thermal oxidation process or an atomic layer deposition process, and said first passivation layer is formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O_{X}, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSe_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSe_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.

10. The control method of claim 6, wherein each nanocrystal is formed of one selected from the group consisting of Ge, ZnO, ZnS, PbS, CdSe, CdTe, CdS, ZnSe, InAs, InP, CdSe(core)/CdS(shell) core-shell structure, CdSe(core)/ZnS(shell) core-shell structure, and CdTe(core)/CdS(shell) core-shell structure, the first passivation layer is formed by an atomic layer deposition process, and said first passivation layer is formed of one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, PO_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS₁₋ₓSeₓ, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS₁₋ₓSeₓ, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, and a mixture therebetween.
